(19) United States
(12) Patent Application Publication
(10) Pub. No.: US 2025/0286534 A1
(43) Pub. Date: Sep. 11, 2025

(54) TRANSDUCER RESONANCE NOISE REDUCTION USING A LOW-PASS FILTER

(71) Applicant: QUALCOMM Incorporated, San Diego, CA (US)

(72) Inventor: Kevin James MCLAUGHLIN, Hollis, NH (US)

(21) Appl. No.: 18/600,239

(22) Filed: Mar. 8, 2024

(51) Int. Cl. H03H 17/02; H03H 17/00; H03M 1/12

(52) U.S. Cl. CPC H03H 17/0248; H03M 1/125; H03H 2017/0072

(57) ABSTRACT

In some aspects, a transducer of a system may convert an input to an analog signal. An analog-to-digital converter of the system may convert the analog signal to a digital signal. A low-pass filter of the system may filter the digital signal to create a filtered digital signal. The filtering of the digital signal reduces noise near a resonance frequency of the transducer. Numerous other aspects are described.

### FIELD OF THE DISCLOSURE

Aspects of the present disclosure generally relate to a transducer and, for example, to filtering to reduce noise frequency from a resonance frequency of a transducer.

### BACKGROUND

A transducer is a device that converts energy from one form to another. For example, a transducer may be designed to convert a physical quantity, such as sound, temperature, or pressure, to an electrical signal. Examples of transducers include microphones, thermometers, and loudspeakers, among numerous other examples. A transducer can take the form of, for example, a micro-electromechanical systems (MEMS) device.

### SUMMARY

In some implementations, a system includes a transducer to convert an input to an analog signal; an analog-to-digital converter (ADC) to convert the analog signal to a digital signal; and a low-pass filter (LPF) to filter the digital signal to create a filtered digital signal, wherein the LPF is configured such that noise near a resonance frequency of the transducer is reduced in the filtered digital signal.

In some implementations, a system includes a transducer to provide an analog signal in response to an input; an ADC to convert an ADC input to a digital signal; and an LPF to filter an LPF input and provide a filtered output, wherein the LPF is configured such that noise associated with resonance of the transducer is reduced in the filtered output.

In some implementations, a method includes converting, by a transducer of a system, an input to an analog signal; converting, by an ADC of the system, the analog signal to a digital signal; and filtering, by an LPF of the system, the digital signal to create a filtered digital signal, wherein the filtering of the digital signal reduces noise near a resonance frequency of the transducer and reduces a sensitivity increase of the transducer in a particular frequency range.

Aspects generally include a method, apparatus, system, user device, user equipment, wireless communication device, and/or processing system as substantially described with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIGS. 1A-1B are examples of a sensitivity diagram and a noise diagram, respectively, for an example transducer in the form of a MEMS microphone.

FIGS. 2A-2B are diagrams of example implementations of a system capable of performing transducer resonance noise reduction using an LPF, in accordance with the present disclosure.

FIGS. 3A-3D are diagrams associated with an example of noise and sensitivity improvement enabled by transducer resonance noise reduction using an LPF, in accordance with the present disclosure.

FIG. 4 is a table illustrating examples of signal-to-noise ratio (SNR) improvement enabled by transducer resonance noise reduction using an LPF, in accordance with the present disclosure.

FIG. 5 is a flowchart of an example process associated with transducer resonance noise reduction using an LPF, in accordance with the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. One skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

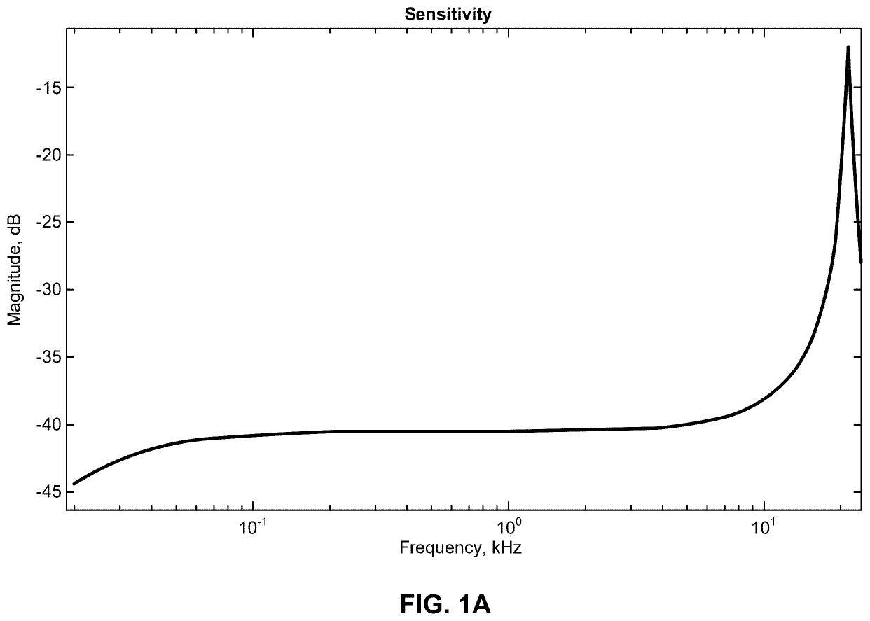

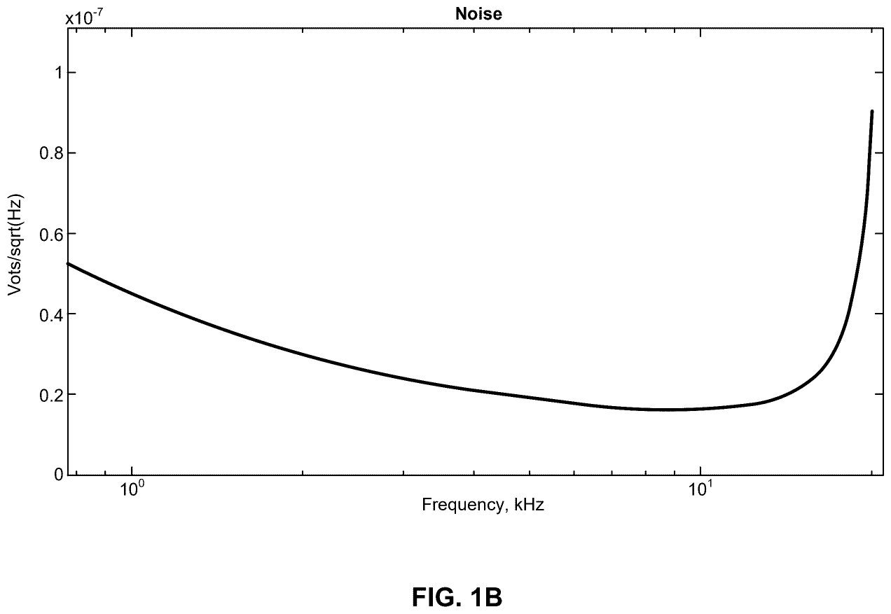

A transducer, such as a transducer in the form of a MEMS microphone, may have a resonance frequency. In practice, a sensitivity of the transducer may increase as frequency approaches the resonance frequency. FIG. 1A is an example of a sensitivity diagram for an example transducer in the form of a MEMS microphone. In the example shown in FIG. 1A, a resonance frequency of the transducer is at approximately 22 kilohertz (kHz). As illustrated in this example, the sensitivity of the MEMS microphone increases as frequency approaches the resonance frequency of approximately 22 kHz. Noise can increase as the frequency approaches the resonance frequency as well. FIG. 1B is an example of a noise diagram for the MEMS microphone associated with FIG. 1A. As shown in FIG. 1B, the noise of the MEMS microphone increases as frequency approaches the resonance frequency of approximately 22 kHz. Noise from the resonance of the transducer may degrade an overall integrated signal-to-noise ratio (SNR) across a frequency range of interest. For example, in the case of the MEMS microphone associated with FIGS. 1A and 1B, noise from the resonance of the MEMS microphone degrades on overall integrated SNR across an audio band (e.g., from approximately 20 hertz (Hz) to approximately 20 kHz). The noise from the resonance can significantly reduce an SNR specification of the MEMS microphone (e.g., a reduction from approximately 1.5 decibels (dB) to approximately 2 dB).

Some implementations described herein enable transducer resonance noise reduction using a low-pass filter (LPF). In some aspects, a system comprises a transducer to convert an input to an analog signal, and an ADC to convert the analog signal to a digital signal. The system further comprises an LPF to filter the digital signal to create a filtered digital signal. Here, the LPF may be configured such that noise near a resonance frequency of the transducer is reduced in the filtered digital signal (e.g., as compared to the unfiltered digital signal as provided by the ADC). Similarly, the LPF may be configured such that an increase in sensitivity of the transducer in a particular frequency range is reduced in the filtered digital signal (e.g., as compared to the unfiltered digital signal as provided by the ADC). In some aspects, as indicated above, the LPF may be a digital filter. Alternatively, the LPF may in some aspects be an analog filter (e.g., filtering can be performed in the analog domain, prior to analog-to-digital conversion), as described in further detail below.

In some aspects, the techniques and apparatuses described herein reduce noise caused by resonance of a transducer, which improves an SNR of a signal provided by a system comprising the transducer (e.g., as compared to a signal that would be provided by the system without filtering). Additionally, or alternatively, the techniques and apparatuses described herein can reduce an increase in sensitivity of the transducer (e.g., flatten a sensitivity curve of the transducer) in a frequency range of interest, meaning that variation in sensitivity of the transducer is reduced in the frequency range of interest, thereby improving performance and reliability of the transducer. Additional details are provided below.

Notably, a resonance frequency of some conventional transducers may be significantly higher than a frequency range of interest. Thus, when using a conventional transducer, noise and sensitivity of the transducer in the frequency range of interest may not be significant and, therefore, filtering is not conventionally implemented. However, such conventional transducers are disadvantageous in some scenarios in that the noise is higher and sensitivity is lower in the frequency range of interest. A more optimized transducer may be capable of reduced noise and higher sensitivity. However, as indicated above, a resonance frequency of such a transducer may be nearer to a frequency range of interest in a given application. Therefore, a technique is needed to address the issue of increased noise and sensitivity caused by the resonance of such a transducer.

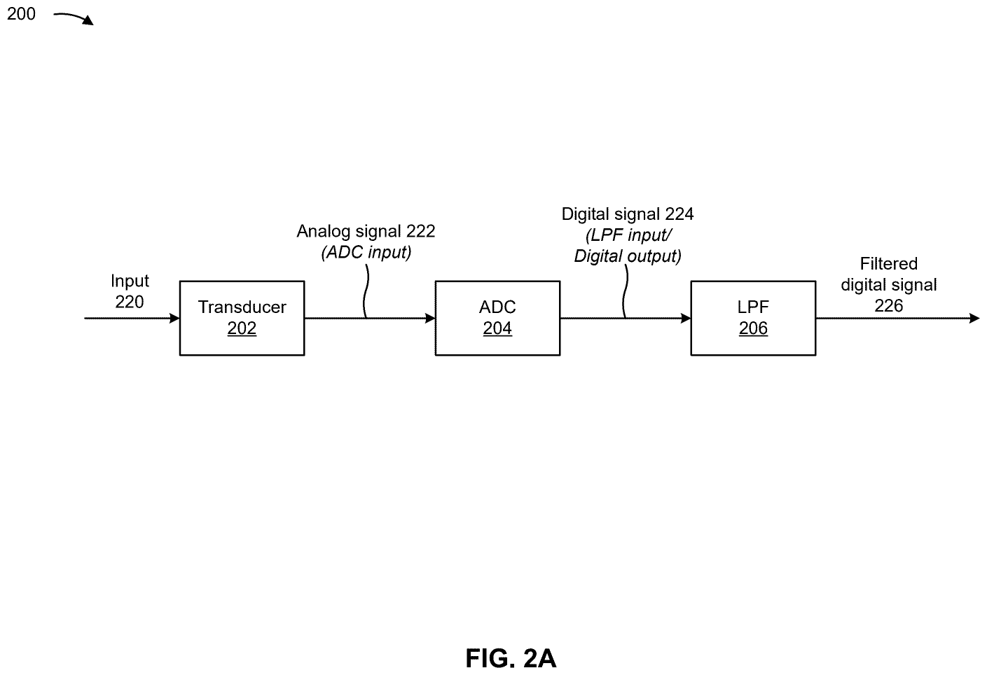

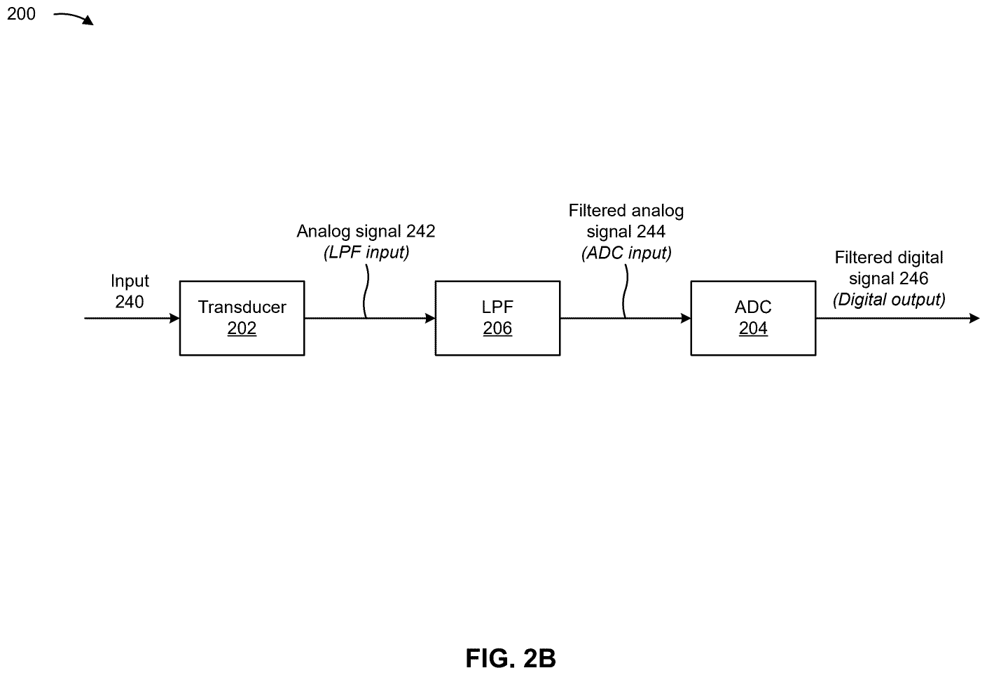

FIGS. 2A-2B are diagrams of a system 200 capable of performing transducer resonance noise reduction using an LPF, in accordance with the present disclosure. As shown in FIGS. 2A and 2B, the system 200 may include a transducer 202, an ADC 204, and an LPF 206. Components of the system 200 are described below, followed by an example of operation of the system 200.

The transducer 202 includes one or more components capable receiving an input 220 and converting the input 220 to an analog signal 222. That is, the transducer 202 may comprise one or more components that, in response to an input 220, provide an analog signal 222 as an output. More generally, the transducer 202 may comprise one or more components that convert energy from one form to another. For example, the transducer 202 may be configured to convert a physical quantity (e.g., sound, temperature, pressure, or the like) to an analog electrical signal. In some aspects, the transducer 202 may comprise a MEMS device. Additionally, or alternatively, the transducer 202 may comprise a microphone, a thermometer, or a loudspeaker, among other examples. As one particular example, the transducer 202 may in some aspects comprise a MEMS microphone. In some aspects, the transducer 202 may have a resonance frequency near (e.g., within a few kHz of) a range of interest associated with an application in which the transducer 202 is to be used. For example, a transducer 202 in the form of a MEMS microphone may have a resonance frequency in a range from approximately 16 kHz to approximately 30 kHz. In one particular example, the transducer 202 in the form of a MEMS microphone may have a resonance frequency of approximately 22 kHz, which may be near an audio band (e.g., from approximately 20 Hz to approximately 20 kHz) in which the MEMS microphone is to be used.

The ADC 204 includes one or more components to convert an analog input to the ADC 204 (herein referred to as an ADC input) to a digital signal. For example, in the implementation of the system 200 shown in FIG. 2A, filtering is performed after analog-to-digital conversion (i.e., the LPF 206 is a digital filter). Here, the ADC 204 converts the analog signal 222 provided by the transducer 202 to a digital signal 224, and the digital signal 224 is provided as an LPF input to the LPF 206 for filtering. As another example, in the implementation of the system 200 shown in FIG. 2B, filtering is performed prior to analog-to-digital conversion (i.e., the LPF 206 is an analog filter). Here, the ADC 204 converts a filtered analog signal 244 provided by the LPF 206 to a filtered digital signal 246, and the filtered digital signal 246 is provided as an output of the system 200. Notably, the system 200 may in some aspects not include an ADC 204. In such a case, an output of the system 200 may be a filtered analog signal 244 provided by the LPF 206 based on filtering an analog signal 242 provided by the transducer 202.

The LPF 206 includes one or more components to filter an input to the LPF 206 (herein referred to as an LPF input) and provide a filtered output. For example, in the implementation of the system 200 shown in FIG. 2A, filtering is performed after analog-to-digital conversion (i.e., the LPF 206 is a digital filter). Here, the LPF 206 filters the digital signal 224 (e.g., the digital output of the ADC 204) to create a filtered digital signal 226, and the filtered digital signal 226 is provided as an output of the system 200. As another example, in the implementation of the system 200 shown in FIG. 2B, filtering is performed prior to analog-to-digital conversion (i.e., the LPF 206 is an analog filter). Here, the LPF 206 filters an analog signal 242 provided by the transducer 202 to create a filtered analog signal 244, and the filtered analog signal 244 is provided as the ADC input to the ADC 204.

In some aspects, the LPF 206 may have a corner frequency in a range from approximately 5 kHz to approximately 20 kHz. In some aspects, the corner frequency of the LPF is configurable (e.g., by a controller of the system 200, not shown). For example, the corner frequency of the LPF 206 may in some aspects be configured via a multi-bit input value (e.g., a 5-bit input value, a 7-bit input value, or the like) that is provided to (e.g., and stored by) the LPF 206. In some aspects, the LPF 206 may have a sample rate in a range from approximately 600 kHz to approximately 6 megahertz (MHz). In some aspects, the LPF 206 may include a single-pole infinite impulse response (IIR) filter. Additionally, or alternatively, the LPF 206 may comprise one or more other types of filter structures. For example, the LPF 206 may in some aspects comprise a single-pole IIR filter and a sinc filter. In general, the LPF 206 may comprise any type of filter structure that can be used to provide low-pass filtering of the LPF input.

In some aspects, the filtering provided by the LPF 206 reduces noise associated with resonance of the transducer 202 in a filtered output (e.g., the filtered digital signal 226, the filtered analog signal 244) provided by the LPF 206. As a result, an SNR of an output of the system 200 is improved (e.g., as compared to an SNR of an output without filtering). As an example, in some aspects, an SNR of the LPF 206 input (e.g., the digital signal 224 in FIG. 2A or the analog signal 242 in FIG. 2B) is improved by approximately 1 dB in the filtered output (e.g., the filtered digital signal 226 in FIG. 2A or the filtered analog signal 244 in FIG. 2B).

Further, in some aspects, the filtering provided by the LPF 206 reduces an increase in sensitivity of the transducer 202 in a particular frequency range in the filtered output provided by the LPF 206. That is, the filtering provided by the LPF 206 can flatten a sensitivity curve of the transducer 202 in a frequency range of interest (e.g., an audio band), meaning that variation in sensitivity of the transducer 202 is reduced in the frequency range of interest, thereby improving performance and reliability of the transducer 202.

In the example system 200 shown in FIG. 2A, the LPF 206 is a digital filter, and analog-to-digital conversion is therefore performed after filtering by the LPF 206. In operation of the system 200 shown in FIG. 2A, the transducer 202 receives an input 220 and converts the input 220 to an analog signal 222. The analog signal 222 is provided to the ADC 204. The ADC 204 receives the analog signal 222 and converts the analog signal 222 to a digital signal 224. The digital signal 224 is provided to the LPF 206. The LPF 206 receives the digital signal 224 and filters the digital signal 224 to create a filtered digital signal 226. The filtered digital signal 226 is provided as an output of the system 200. In some aspects, the filtered digital signal 226 can be provided to another component or system for further processing.

In the example system 200 shown in FIG. 2B, the LPF 206 is an analog filter, and analog-to-digital conversion is therefore performed prior to filtering by the LPF 206. In operation of the system 200 shown in FIG. 2B, the transducer 202 receives an input 240 and converts the input 240 to an analog signal 242. The analog signal 242 is provided to the LPF 206. The LPF 206 receives the analog signal 242 and filters the analog signal 242 to create a filtered analog signal 244. The filtered analog signal 244 is provided to the ADC 204. The ADC 204 receives the filtered analog signal 244 and converts the filtered analog signal 244 to a filtered digital signal 246. The filtered digital signal 246 is provided as an output of the system 200. In some aspects, the filtered digital signal 246 can be provided to another component or system for further processing.

As indicated above, FIGS. 2A-2B are provided as examples. Other examples may differ from what is described with regard to FIGS. 2A-2B. The number and arrangement of components shown in FIGS. 2A-2B are provided as an example. In practice, there may be additional components, fewer components, different components, or differently arranged components than those shown in FIGS. 2A-2B. Furthermore, two or more components shown in FIGS. 2A-2B may be implemented within a single component, or a single component shown in FIGS. 2A-2B may be implemented as multiple, distributed components. Additionally, or alternatively, a set of components (e.g., one or more components) shown in FIGS. 2A-2B may perform one or more functions described as being performed by another set of components shown in FIGS. 2A-2B.

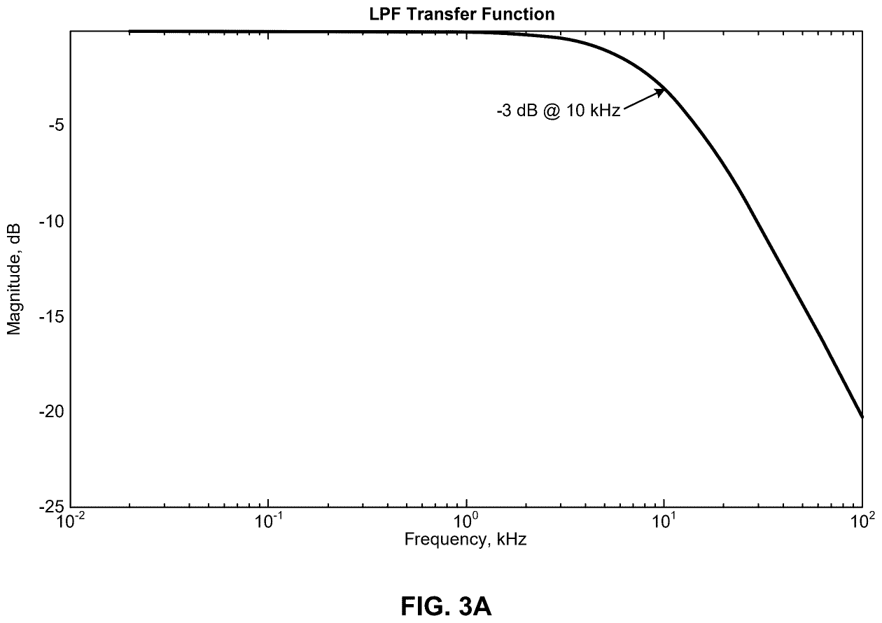

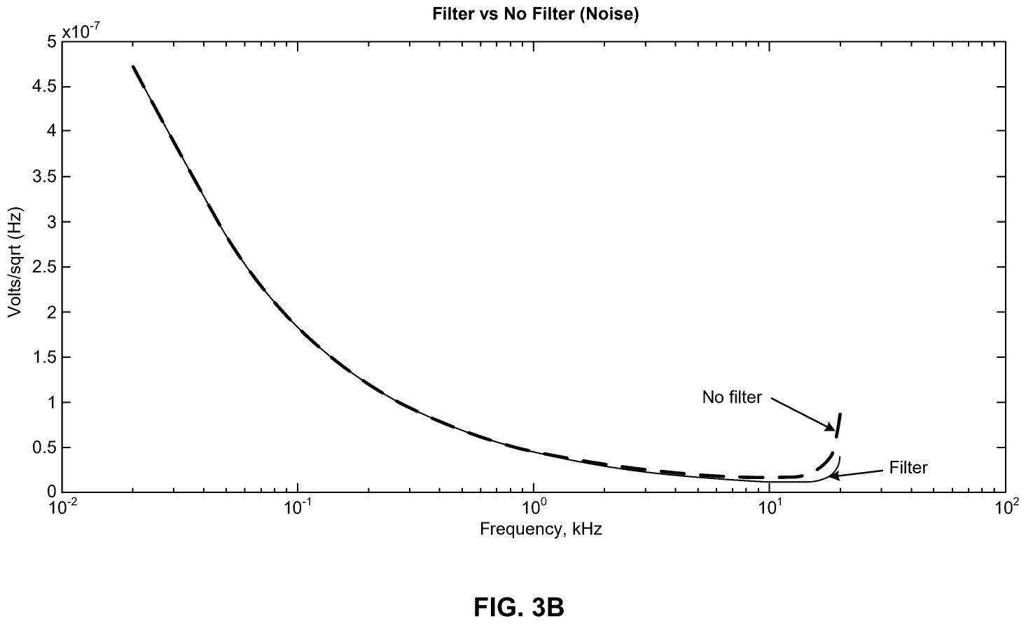

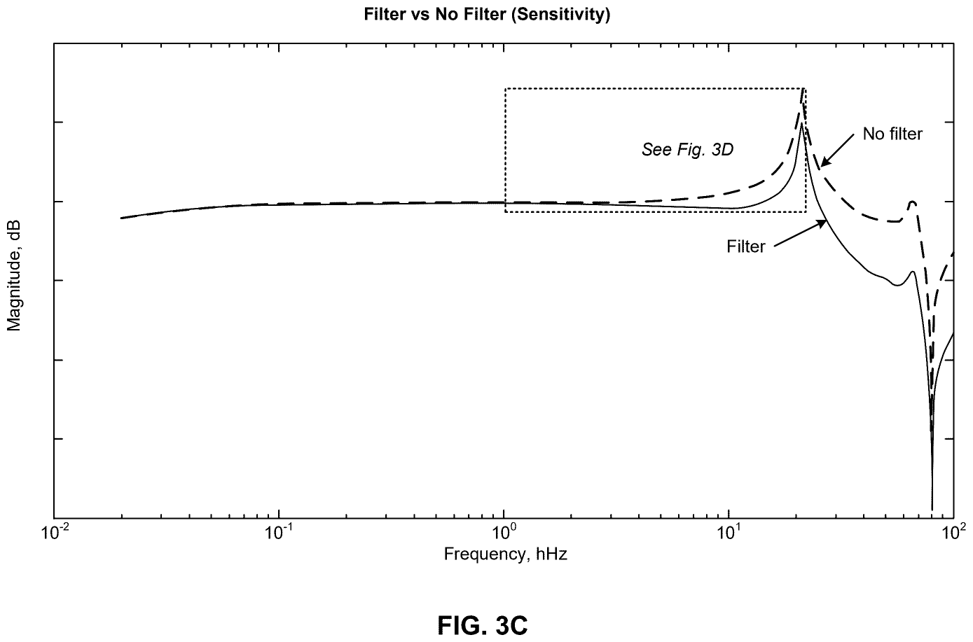

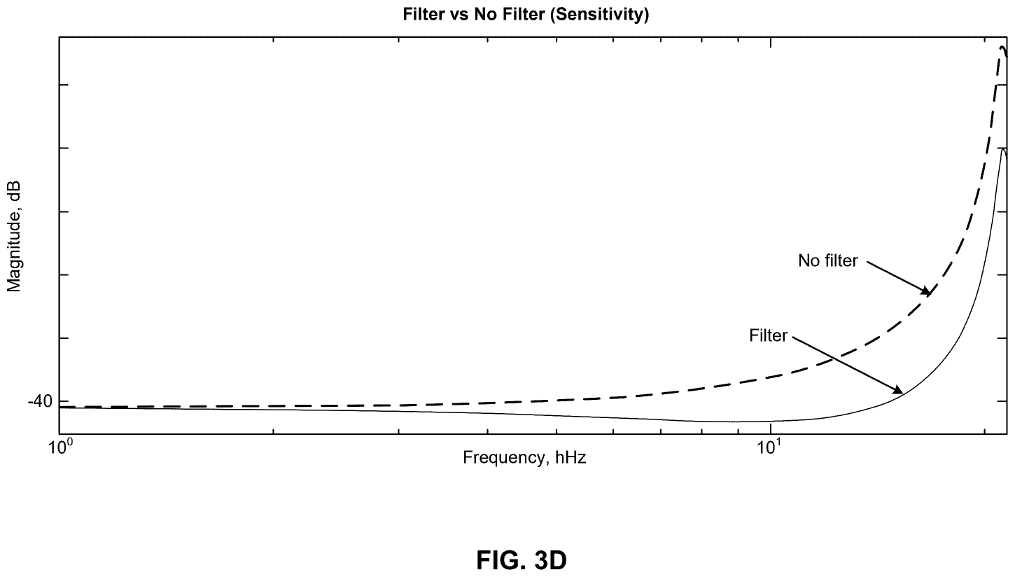

FIGS. 3A-3D are diagrams associated with an example of noise and sensitivity improvement provided by transducer resonance noise reduction using an LPF, in accordance with the present disclosure.

FIG. 3A is a diagram illustrating a transfer function of an example of an LPF 206 that can be used to provide resonance noise reduction for a transducer 202 in the form of a MEMS microphone. In this example, as illustrated in FIG. 3A, the LPF 206 has a first order response with a −3 dB point of approximately 10 kHz.

FIG. 3B is a diagram illustrating the noise reduction provided by the LPF 206 associated with FIG. 3A. Here, a total SNR improvement due to the filtering provided by the LPF 206 is 1.2 dB.

FIGS. 3C and 3D are diagrams illustrating the flattening of a sensitivity curve provided by the LPF 206 associated with FIG. 3A. As shown in FIGS. 3C and 3D, the sensitivity of the transducer 202 is comparatively flatter (e.g., has a smaller increase) between approximately 20 Hz and 20 kHz.

Notably, while FIGS. 3A-3D show a first order response for the (digital) LPF 206, the LPF 206 could in some aspects have a higher order response and/or another (more complex) response to provide similar or improved noise reduction.

As indicated above, FIGS. 3A-3D are provided as examples. Other examples may differ from what is described with regard to FIGS. 3A-3D.

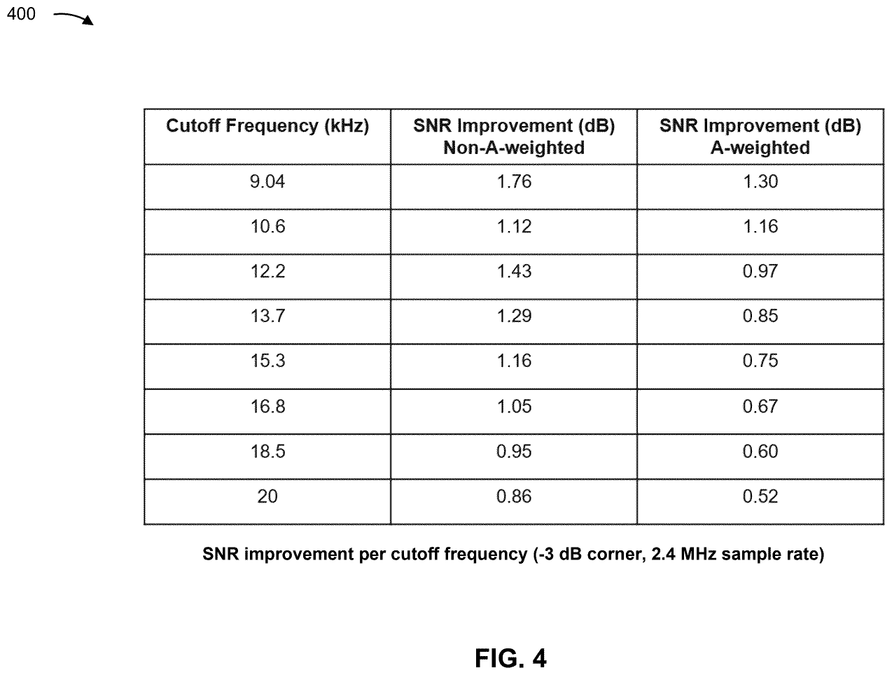

FIG. 4 is a table 400 illustrating examples of SNR improvement provided by transducer resonance noise reduction using an LPF, in accordance with the present disclosure. With respect to table 400, the LPF 206 has a −3 dB corner and a sampling rate of 2.4 MHz. The table 400 shows non-average-weighted and average-weighted SNR improvements (in dB) for various cutoff frequencies ranging from 9.04 kHz to 20 kHz. As illustrated by the table 400, the filtering provided by the LPF 206 provides SNR improvement for a variety of cutoff frequencies. Similar SNR improvements would also be achieved for sampling rates other than 2.4 MHz.

As indicated above, FIG. 4 is provided as an example. Other examples may differ from what is described with regard to FIG. 4.

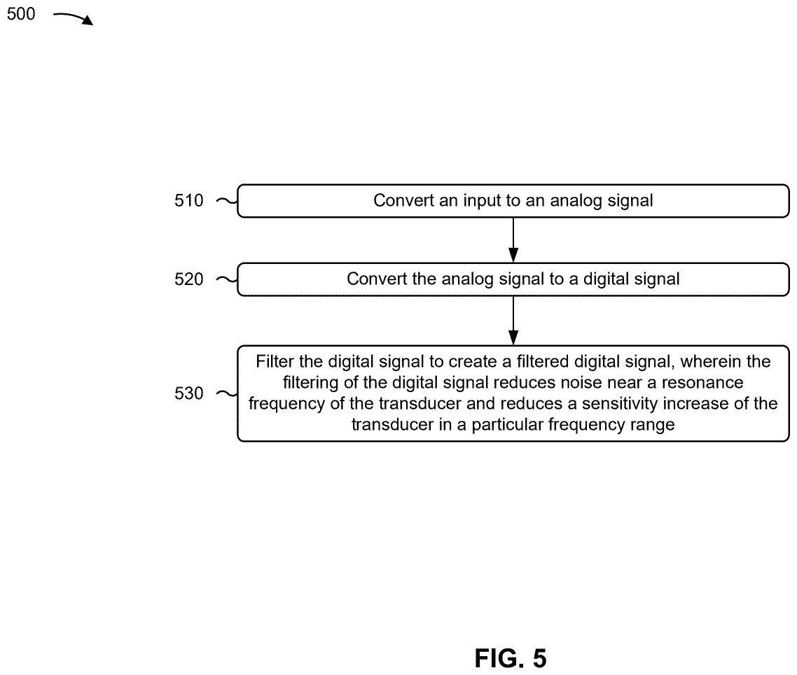

FIG. 5 is a flowchart of an example process 500 associated with transducer resonance noise reduction using a low-pass filter, in accordance with the present disclosure. In some aspects, one or more process blocks of FIG. 5 are performed by one or more components of a system (e.g., system 200).

As shown in FIG. 5, process 500 may include converting an input to an analog signal (block 510). For example, a transducer of the system (e.g., a transducer 202) may convert an input to an analog signal, as described above.

As further shown in FIG. 5, process 500 may include converting the analog signal to a digital signal (block 520). For example, an ADC of the system (e.g., an ADC 204) may convert the analog signal to a digital signal, as described above.

As further shown in FIG. 5, process 500 may include filtering the digital signal to create a filtered digital signal, wherein the filtering of the digital signal reduces noise near a resonance frequency of the transducer and reduces a sensitivity increase of the transducer in a particular frequency range (block 530). For example, an LPF of the system (e.g., an LPF 206) may filter the digital signal to create a filtered digital signal, wherein the filtering of the digital signal reduces noise near a resonance frequency of the transducer and reduces a sensitivity increase of the transducer in a particular frequency range, as described above.

Process 500 may include additional aspects, such as any single aspect or any combination of aspects described below and/or in connection with one or more other processes described elsewhere herein.

In a first aspect, the transducer comprises a MEMS device.

In a second aspect, alone or in combination with the first aspect, the transducer comprises a microphone.

In a third aspect, alone or in combination with any of the first and second aspects, an SNR of the digital signal is improved by approximately 1 dB in the filtered digital signal.

In a fourth aspect, alone or in combination with any of the first through third aspects, the resonance frequency of the transducer is in a range from approximately 16 kHz to approximately 30 kHz.

In a fifth aspect, alone or in combination with any of the first through fourth aspects, a corner frequency of the LPF is configurable via a multi-bit input value (e.g., a 7-bit value).

In a sixth aspect, alone or in combination with any of the first through fifth aspects, a corner frequency of the LPF is in a range from approximately 5 kHz to approximately 20 KHz.

In a seventh aspect, alone or in combination with any of the first through sixth aspects, a sample rate of the LPF is in a range from approximately 600 kHz to approximately 6 MHz.

In an eighth aspect, alone or in combination with any of the first through seventh aspects, the LPF comprises a single-pole IIR filter.

Although FIG. 5 shows example blocks of process 500, in some aspects, process 500 includes additional blocks, fewer blocks, different blocks, or differently arranged blocks than those depicted in FIG. 5. Additionally, or alternatively, two or more of the blocks of process 500 may be performed in parallel.

The following provides an overview of some Aspects of the present disclosure:

Aspect 1: A system, comprising: a transducer to convert an input to an analog signal; an analog-to-digital converter (ADC) to convert the analog signal to a digital signal; and a low-pass filter (LPF) to filter the digital signal to create a filtered digital signal, wherein the LPF is configured such that noise near a resonance frequency of the transducer is reduced in the filtered digital signal.

Aspect 2: The system of Aspect 1, wherein the LPF is configured such that an increase in sensitivity of the transducer in a particular frequency range is reduced in the filtered digital signal.

Aspect 3: The system of any of Aspects 1-2, wherein the transducer comprises a micro-electromechanical systems (MEMS) device.

Aspect 4: The system of any of Aspects 1-3, wherein the transducer comprises a microphone.

Aspect 5: The system of any of Aspects 1-4, wherein a signal-to-noise ratio (SNR) of the digital signal is improved by approximately 1 decibel (dB) in the filtered digital signal.

Aspect 6: The system of any of Aspects 1-5, wherein the resonance frequency of the transducer is in a range from approximately 16 kilohertz (kHz) to approximately 30 kHz.

Aspect 7: The system of any of Aspects 1-6, wherein a corner frequency of the LPF is configurable via a multi-bit input value.

Aspect 8: The system of any of Aspects 1-7, wherein a corner frequency of the LPF is in a range from approximately 5 kHz to approximately 20 KHz.

Aspect 9: The system of any of Aspects 1-8, wherein a sample rate of the LPF is in a range from approximately 600 kHz to approximately 6 MHz.

Aspect 10: The system of any of Aspects 1-9, wherein the LPF comprises a single-pole infinite impulse response (IIR) filter.

Aspect 11: A system, comprising: a transducer to provide an analog signal in response to an input; an analog-to-digital converter (ADC) to convert an ADC input to a digital signal; and a low-pass filter (LPF) to filter an LPF input and provide a filtered output, wherein the LPF is configured such that noise associated with resonance of the transducer is reduced in the filtered output.

Aspect 12: The system of Aspect 11, wherein the ADC input is the analog signal and the LPF input is the digital signal.

Aspect 13: The system of any of Aspects 11-12, wherein the LPF input is the analog signal and the ADC input is the filtered output.

Aspect 14: The system of any of Aspects 11-13, wherein the LPF is configured such that an increase in sensitivity of the transducer in a particular frequency range is reduced in the filtered output.

Aspect 15: The system of any of Aspects 11-14, wherein the transducer comprises a micro-electromechanical systems (MEMS) device.

Aspect 16: The system of any of Aspects 11-15, wherein the transducer comprises a microphone.

Aspect 17: The system of any of Aspects 11-16, wherein a signal-to-noise ratio (SNR) of the LPF input is improved by approximately 1 decibel (dB) in the filtered output.

Aspect 18: A method, comprising: converting, by a transducer of a system, an input to an analog signal; converting, by an analog-to-digital converter (ADC) of the system, the analog signal to a digital signal; and filtering, by a low-pass filter (LPF) of the system, the digital signal to create a filtered digital signal, wherein the filtering of the digital signal reduces noise near a resonance frequency of the transducer and reduces a sensitivity increase of the transducer in a particular frequency range.

Aspect 19: The method of Aspect 18 wherein the transducer comprises a micro-electromechanical systems (MEMS) device.

Aspect 20: The method of any of Aspects 18-19, wherein the transducer comprises a microphone.

Aspect 21: A system configured to perform one or more operations recited in one or more of Aspects 1-20.

Aspect 22: An apparatus comprising means for performing one or more operations recited in one or more of Aspects 1-20.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware and/or a combination of hardware and software. “Software” shall be construed broadly to mean instructions, instruction sets, code, code segments, program code, programs, subprograms, software modules, applications, software applications, software packages, routines, subroutines, objects, executables, threads of execution, procedures, and/or functions, among other examples, whether referred to as software, firmware, middleware, microcode, hardware description language, or otherwise. As used herein, a “processor” is implemented in hardware and/or a combination of hardware and software. It will be apparent that systems and/or methods described herein may be implemented in different forms of hardware and/or a combination of hardware and software. The actual specialized control hardware or software code used to implement these systems and/or methods is not limiting of the aspects. Thus, the operation and behavior of the systems and/or methods are described herein without reference to specific software code, since those skilled in the art will understand that software and hardware can be designed to implement the systems and/or methods based, at least in part, on the description herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various aspects. Many of these features may be combined in ways not specifically recited in the claims and/or disclosed in the specification. The disclosure of various aspects includes each dependent claim in combination with every other claim in the claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A system, comprising:
a transducer to convert an input to an analog signal;
an analog-to-digital converter (ADC) to convert the analog signal to a digital signal; and
a low-pass filter (LPF) to filter the digital signal to create a filtered digital signal, wherein the LPF is configured such that noise near a resonance frequency of the transducer is reduced in the filtered digital signal.

2. The system of claim 1, wherein the LPF is configured such that an increase in sensitivity of the transducer in a particular frequency range is reduced in the filtered digital signal.

3. The system of claim 1, wherein the transducer comprises a micro-electromechanical systems (MEMS) device.

4. The system of claim 1, wherein the transducer comprises a microphone.

5. The system of claim 1, wherein a signal-to-noise ratio (SNR) of the digital signal is improved by approximately 1 decibel (dB) in the filtered digital signal.

6. The system of claim 1, wherein the resonance frequency of the transducer is in a range from approximately 16 kilohertz (kHz) to approximately 30 KHz.

7. The system of claim 1, wherein a corner frequency of the LPF is configurable via a multi-bit input value.

8. The system of claim 1, wherein a corner frequency of the LPF is in a range from approximately 5 kilohertz (kHz) to approximately 20 kHz.

9. The system of claim 1, wherein a sample rate of the LPF is in a range from approximately 600 kilohertz to approximately 6 megahertz.

10. The system of claim 1, wherein the LPF comprises a single-pole infinite impulse response (IIR) filter.

11. A system, comprising:
a transducer to provide an analog signal in response to an input;
an analog-to-digital converter (ADC) to convert an ADC input to a digital signal; and
a low-pass filter (LPF) to filter an LPF input and provide a filtered output, wherein the LPF is configured such that noise associated with resonance of the transducer is reduced in the filtered output.

12. The system of claim 11, wherein the ADC input is the analog signal and the LPF input is the digital signal.

13. The system of claim 11, wherein the LPF input is the analog signal and the ADC input is the filtered output.

14. The system of claim 11, wherein the LPF is configured such that an increase in sensitivity of the transducer in a particular frequency range is reduced in the filtered output.

15. The system of claim 11, wherein the transducer comprises a micro-electromechanical systems (MEMS) device.

16. The system of claim 11, wherein the transducer comprises a microphone.

17. The system of claim 11, wherein a signal-to-noise ratio (SNR) of the LPF input is improved by approximately 1 decibel (dB) in the filtered output.

18. A method, comprising:
converting, by a transducer of a system, an input to an analog signal;
converting, by an analog-to-digital converter (ADC) of the system, the analog signal to a digital signal; and
filtering, by a low-pass filter (LPF) of the system, the digital signal to create a filtered digital signal, wherein the filtering of the digital signal reduces noise near a resonance frequency of the transducer and reduces a sensitivity increase of the transducer in a particular frequency range.

19. The method of claim 18 wherein the transducer comprises a micro-electromechanical systems (MEMS) device.

20. The method of claim 18, wherein the transducer comprises a microphone.
